(19) United States
(12) Patent Application Publication
(10) Pub. No.: US 2010/0033160 A1
(43) Pub. Date: Feb. 11, 2010

(54) Measurements of Redox Potential and Concentration of Redox Active Substances

(76) Inventors: Nikolai Kocherginsky, Urbana, IL (US); Zheng Wang, Singapore (SG)

Correspondence Address: KOCHERGINSKY NIKOLAI M., 909 E. SUNNYCREST DRIVE, URBANA, IL, 61801, US

(21) Appl. No.: 12/189,148

(22) Filed: Aug. 9, 2008

(51) Int. Cl. G01R 19/00

(52) U.S. Cl. 324/72

(57) ABSTRACT

A method to measure redox potentials and concentrations of redox active substances in an aqueous solution is described. The method is based on measurements of transmembrane electric potential through an electroconductive polymer membrane, for example, through a d,l-camphor sulfonic acid (CSA) doped polyaniline (PANI) membrane. Transmembrane electric potential demonstrates good Nernstian response as a function of redox potential in solutions,of the redox couples of Fe²⁺/Fe³⁺ and Fe(CN)₆⁴⁻/Fe(CN)₆³⁻. The membrane gives good response to redox active substances such as L-Ascorbic acid and redox active dyes Neutral red, Nile blue and N-phenylanthranilic acid that do not induce satisfactory response on Pt electrode. The lower detection limits can be as low as 0.2 mM. In the absence of redox processes it is also possible to measure Cl⁻ concentration at least from 0.05 mM to 100 mM.

### CURRENT U.S. CLASS

204/406; 204/230.8 204/418 204/421 422/82 428/332 436/104 436/149

### CURRENT INTERNATIONAL CLASS

G01N 21/77, G01N27/12, G01N27/26, G01N27/30, G01N27/49, G01N27/416

### FIELD OF SEARCH

U.S. Patent Documents

| | | |
|---|---|---|
| 4,963,815 | October 1990 | Hafeman et al. |
| 5,002,700 | March 1991 | Otagawa et al. |
| 5,023,133 | June 1991 | Yodice et al. |
| 5,536,473 | July 1996 | Monkman et al. |
| 5,587,466 | December 1996 | Veil et al. |
| WO9416316(A1) | | Monkman et al. |
| 6,783,989 | August 2004 | Zakin |
| 6,994,777 | February 2006 | Gonzales-Martin et al. |

US Patent application Publications

| | | |
|---|---|---|
| 2004/0235184 A1, | November 2004 | Swager |
| 2005/0126909 A1 | Jun. 16, 2005 | Weiller |

Foreign Patent Documents

| | | |
|---|---|---|
| WO/1994/016316 | July 1994 | Monkman et al. |
| WO/2006/024848 | March 2006 | Piletsky et al. |
| WO/2006/074541 | July 2006 | Rowe et al. |
| PCT/CA2006/000024 | | Rowe |
| WO/2006/087568 | August 2006 | Higson et al. |
| PCT/GB2006/000565 | | Higson |
| TW 577982B | March 2004 | Chen Nan-Ming et al. |

### OTHER REFERENCES

1. W. M. Clark, Oxidation-Reduction Potentials of Organic Systems, Williams and Wilkins, Baltimore, 1960.

2. G. Wallace et al., Conductive Electroactive Polymers: Intelligent Materials Systems, 2d. Edition, CRC Press, 2002.

3. P. Chandrasekhar, Conductive Polymers, Fundamentals and Applications: A Practical Approach, Kluwer, 1999.

4. J. Huang et. al., Chem. Eur. J. 10, 2004, 1314

5. T. V. Shishkanova et al., Analytica Chimica Acta, 553, 2005, 160

6. Zhou D-M et al, Electroanalysis 9, 1997, 1185

7. J. Bobacka et al., Electroanalysis 15, 2003, 366

8. A. Michalska et al., Electroanalysis 17, 2005, 327

9. K. Grennan et al., Electroanalysis 17, 2005, 1360

10. Z. Mousavi et al., Electroanalysis 17, 2005, 1609

11. J. Bobacka et al., Electroanalysis 18, 2006, 7

12. G. Khripoun et al., Electroanalysis 18, 2006, 1322

13. N. Ferrer-Anglada et al., Phys. Stat. Sol. (b). 243, 2006, 3519.

14. Lei Zhang et al., J. Electroanalytical Chemistry, 568, 2004, 189.

15. S. Tan et al, J. Phys. Chem. B, 109, 2005, 23480.

16. C. A. Amarant et al., Polym. Adv. Tech.16, 2005, 420

17. W. Lei, N. M. Kocherginsky, Synth. Met. 106, 1999, 19

18. W. Lei, N. M. Kocherginsky, React. Funct. Polym. 45, 2000, 65

19. W. Lei, N. M. Kocherginsky, J. Membr. Sci. 167, 2000, 135

20. N. M. Kocherginsky, W. Lei, Z. Wang, J. Phys. Chem. A 109, 2005, 4010

21. N. M. Kocherginsky, Z. Wang, React. Func. Polym. 66, 2006, 1384

### DESCRIPTION

1. Field of the Invention

This invention relates to the analytical chemistry, specifically to the improved methods of measurements of redox potential and also methods to measure the content of redox active substances in aqueous solutions.

2. Background of the Related Art

Oxidation/reduction potential is an important parameter, related with many other properties and processes both in aqueous solutions and cell metabolism [W. M. Clark, Oxidation-Reduction Potentials of Organic Systems, Williams and Wilkins, Baltimore, 1960]. The most well known electrodes for measurements of redox potentials in aqueous solutions are Platinum (“Pt”) metal electrodes, but they can be used only in a few systems, such as Fe²⁺/Fe³⁺ and Fe(CN)₆⁴⁻/Fe(CN)₆³. Many redox active organic substances cannot be measured with Pt electrodes because there is only a small electrical exchange current on the electrode surface, and because of the surface poisoning with many biomolecules, including those with SH groups. One well known and important reducing agent which cannot be directly measured with Pt electrodes is vitamin C, ascorbic acid.

The use of an amperometric membrane-based sensor to measure redox active species is described in WO/2006/074541and PCT/Ca2006/000024. The sensor is sensitive to chlorine and chloroamines and consists of a liquid membrane with a first redox carrier, for example quinone, and another redox carrier, for example vanadate, in the electrolyte space between the membrane and metal (Pt) electrode. The disadvantage of this method is that the membrane can change its electrical resistance because of ion transport through the membrane, and also losses of quinone from the membrane with time.

A photoresponsive electrode for determination of the redox potential is disclosed in the U.S. Pat. No. 4963815. The presence and amount of an analyte can be determined by measuring a redox potential-modulated signal using photoresponsive element. The element is partially covered with an electronically conductive layer and partially with a protective insulative layer. The disadvantage of this method is that the signal depends on the light intensity and cannot be used for investigation of light sensitive substances.

Conductive electroactive polymers, also called synthetic metals, are relatively new materials. They combine properties of both metals and polymers and they already have found many practical applications. Polyaniline (PANI) is one of the most popular synthetic metals because it is easy to make and has good mechanical properties. Initially nonelectroconductive, it can be chemically doped or modified so that its electrical conductivity is increased by billions of times. This effect is observed, for example, at acidic pH. PANI attracted special interest because of its easy polymerization, favorable electrochemical activity and environmental stability. Its electro-conductivity can be increased from that of insulator (10⁻¹⁰˜10⁻⁵ Ohm⁻¹cm⁻¹) to the values typical for conductors (2˜5 Ohm⁻¹cm⁻¹) by treatment with HCl, or even to the metal regime (400 Ohm⁻¹cm⁻¹) being doped with d,l-camphor sulfonic acid (PANI-CSA).

The color of polyaniline can vary depending on the pH, and it is effected by other substances, including redox agents, thus making it possible to make a sensing apparatus (WO/2006/087568, PCT /GB2006/000565) and even detect food spoilage (WO 2006/024848). Though the color changes can be determined in a simple qualitative test, this test has a low sensitivity. Quantitative measurements must be based on a sophisticated apparatus.

Polyaniline based sensors, including those based on nanofibers, are used in analytical chemistry as amperometric sensors when external voltage is applied to a polymer and electrical current is measured. Examples are chlorine sensor [TW577982B], H₂S and SO₂ sensor [U.S. Pat. No. 5,536,473 and WO9416316 (A1)].

A device, based on measurements of an electrical current and comprising a plurality of sensor elements for detecting the presence of an analyte in a fluid is disclosed in U.S. Pat. No. 6,994,777. Each sensor element in this case has a pair of electrodes and an electronically conducting polymer composition, including polyaniline, in contact between the pair of electrodes.

Polyaniline-camphorsulfonic acid composite films are more chemically stable and can be used in cyclic voltammetry together with Pt electrodes to measure ascorbic acid in the range 5-50 mM [Lei Zhang and Shaojun Dong, J. Electroanalytical Chemistry, 568 (2004) 189-194].

Conductivity of this polyconjugated polymer is sensitive to chemical vapors, which served the development of vapor sensitive chemiresistors [J. Huang et. al., Chem. Eur. J. 10, 2004, 1314]

The disadvantage of the electrochemical voltammetry methods is that the current is often nonlinearly dependent on applied voltage, and the method for measurement in aqueous solutions is not sensitive enough.

Potentiometric sensors have several advantages in comparison to the sensors based on measurements of electric current. They are based on measurements of electrical potential spontaneously generated on the membrane and do not need any application of external electrical field. Potentiomertric sensors with different conductive polymer membranes are known and can be used to detect charged ions [J. Bobacka et al., Electroanalysis 15, 2003, 366]. For example, polyaniline based ion-selective electrode is sensitive to pH [N. Ferrer-Anglada et al., Phys. Stat. Sol. (b). 243, 2006, 3519] and can be used for anion recognition [T. V. Shishkanova et al., Analytica Chimica Acta, 553, 2005, 160], including nitrate [G. Khripoun et al., Electroanalysis 18, 2006, 1322]. Potentiometric sensors based on polyaniline and sensitive to different redox active substances and also to redox potential in aqueous solutions at pH near neutral are not known.

### OBJECTS AND ADVANTAGES

The present invention discloses a new method of direct measurement of redox potential and concentrations of different inorganic and organic redox active substances, including ascorbic acid and different redox active dyes, in aqueous solutions. The method does not use Pt electrodes and has a lower limit of sensitivity better than that of cyclic voltammetry. Further objects and advantages of the invention will become apparent from a consideration of the drawings and ensuing description.

### SUMMARY OF THE INVENTION

The method is based on the application of electroactive polymer-based membrane, where the polymer is, for example, doped polyaniline. Doping can be achieved with d,l-camphor sulfonic acid (CSA) and other organic acids with the relatively large-sized molecule, making PANI electroconductive in aqueous solutions, including those at neutral pH.

Calibration results demonstrate good Nernstian response and satisfactory low detection limits for different redox substances, including those which cannot be properly measured by conventional Pt redox electrodes. In the absence of a redox active species, the method can be used to measure chloride in the range at least from 0.05 mM to 0.1 M.

### BRIEF DESCRIPTION OF THE DRAWINGS

FIG. 1 shows the typical kinetics of transmembrane electric potential formation after several additions of K₃Fe(CN)₆ to the solution.

FIG. 2. presents the transmembrane potential as a function of the logarithm concentration of K4Fe(CN)₆ and K₃Fe(CN)₆ (a and b, respectively).

FIG. 3 demonstrates similar changes of transmembrane potential for Fe²⁺ and Fe³⁺ (a and b, respectively).

FIG. 4 demonstrates linear response of transmembrane potential vs. the logarithm of ascorbic acid concentration at pH 2.7, 4.4, and 6.8, respectively.

FIG. 5 demonstrates redox potentials in the oxidizing and reducing phases as a function of time during transmembrane redox reaction between acidic solutions of separated by the membrane FeCl₂ and FeCl₃.

FIG. 6 presents comparison of the transmembrane potential and the difference of two redox potentials in liquid phases during transmembrane redox reaction.

FIG. 7 demonstrates transmembrane potential as a function of time for redox reaction of K₃Fe(CN)₆ and K₄Fe(CN)₆ at pH 6.4 across PANI-CSA membrane and effect of KCl added to the ferricyanide solution.

FIG. 8 shows transmembrane potential as a function of the logarithm of K₃Fe(CN)₆ concentration in the presence of 1M KCl.

FIG. 9 presents transmembrane potential as a function of the logarithm of FeCl₃ concentration in 0.1M HCl+1M KCl (a) and in 1M HCl (b).

FIG. 10. Transmembrane potential as a function of the logarithm of KCl concentration ratio in one solution (C₁) to the other (C₂).

Table 1 presents calibration results for the redox active dyes Neutral Red, Nile Blue and N-phenylanthranilic acid.

Experimental

Reagents

Aniline was purified by distillation prior to use. Following reagents were used as received: Ammonium Persulfate, camphor-10-sulfonic acid monohydrate, m-cresol, HCl (35%), N-methyl-2-pyrolidine, EDTA Disodium salt, Iron (III) Chloridex6H₂O, Iron(II) Chloridex4H₂O, Potassium Ferricyanide and Potassium Ferrocyanide, Ascorbic Acid (standard redox potential 0.06V vs. NHE), Neutral Red (3-Amino-7-dimethylamino-2-methylphenazine hydrochloride, standard redox potential −0.29V vs. NHE), Nile Blue (standard redox potential −0.12V vs. NHE), N-Phenylanthranilic acid (standard redox potential 0.89V vs. NHE).

Chemical Synthesis of PANI-CSA Membranes

Aniline was polymerized in 1M HCl solution at 0° C. with the addition of cold ammonium persulphate solution as the initiator. Produced PANI was in emeraldine salt (ES) form, and was converted to emeraldine base (EB) by immersing in NH₄OH solution for 8 hours. Freshly collected EB powder was mixed with vacuo dried CSA powder at a ratio of 1:2. The mixture was dissolved in m-cresol gradually at a concentration of 15 g/L. Subsequently the polymer solution was poured into flat Petri dishes to cast PANI-CSA membranes in a freeze dryer. The membrane thickness was ˜80 μm.

Potentiometric Calibrations

Measurements were conducted in a Teflon chamber with two compartments, separated by a free-standing PANI-CSA membrane. Initially, one of the compartments was filled with an oxidizing reagent (if reducing reagent was added step by step to the opposite side of the membrane) or a reducing reagent (if the oxidizing reagent was then added). The solution was pre-equilibrated with the PANI-CSA membrane for several hrs until the redox potential in this solution became relatively stable. Simultaneously the opposite compartment was filled with 0.1M HCl or buffer solutions adjusted according to the necessary pH. During calibrations, 10 μL (or specified in the text otherwise) aliquots of concentrated calibration solution were intermittently injected into the buffer using a pipette. After each addition the transmembrane potential was recorded with a pair of saturated with KCl Ag/AgCl electrodes.

Transmembrane Redox Reactions

An oxidizing solution of 0.01M FeCl₃ in 0.1M HCl was added into one compartment and simultaneously the other compartment was filled with the reducing solution of 0.01M FeCl₂ in 0.1M HCl. Measurements of redox potential in both solutions with Pt electrode versus Ag/AgCl electrode, and also measurements of transmembrane potential using a pair of Ag/AgCl electrodes with agar-agar salt bridges were commenced upon the addition of redox reagents.

### EXAMPLES

Invention will be more readily understood by reference to the following examples, which are included merely for the purpose illustration of certain aspects and embodiments of the present invention, and are not intended to limit the invention.

Potentiometric Calibrations

The electrical resistance of a CSA-doped PANI membrane, separating two aqueous solutions, was a few ohms. During redox calibrations, after a few minutes of incubation and pre-equilibration of one oxidizing or reducing solution with the membrane, concentrated calibration solution was injected into the opposite compartment intermittently. In a few seconds the transmembrane electric potential was formed and reached the maximal value. Then it gradually and slightly decreased in magnitude.

### Example 1

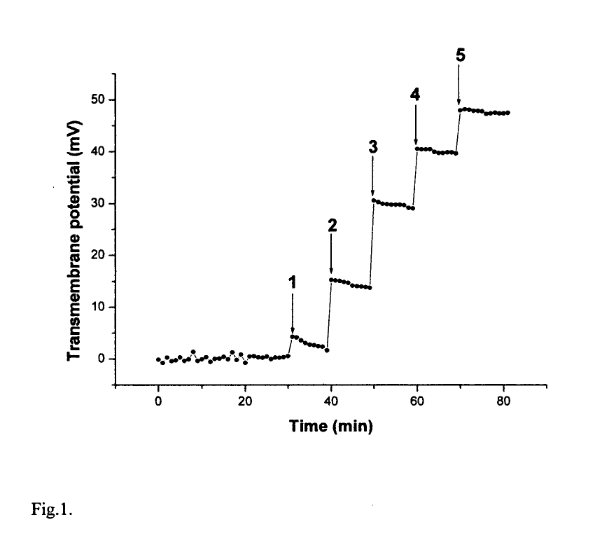

FIG. 1 shows a typical kinetics of transmembrane electric potential formation after several additions of K₃Fe(CN)₆. The opposite solution was 0.01M K₄Fe(CN)₆ in the same buffer. It takes less than couple of minutes to reach maximum potential after each addition. The positive sign of the transmembrane potential corresponds to the direction of electron flow from the reducing to the oxidizing solution, where the reference electrode was inserted. If only ferricyanide was present in both solutions and its concentration in one of the solutions was changed, the effect was not observed.

### Example 2

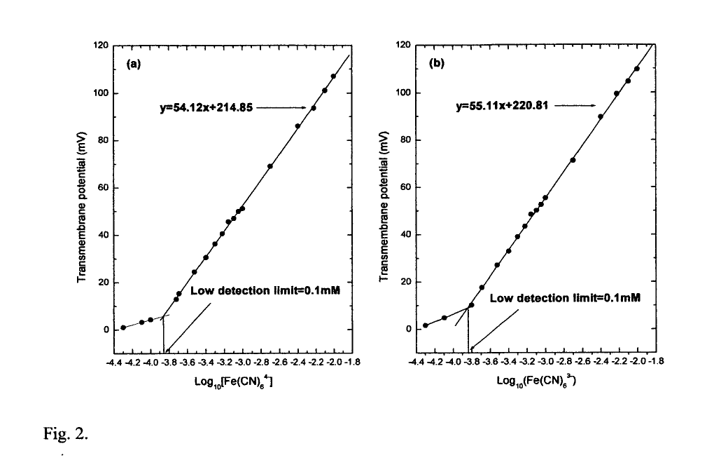

FIG. 2(a, b) presents the calibrations for Fe(CN)₆⁴⁻ and Fe(CN)₆³⁻ based on the maximum potential after each addition. Reducing and oxidizing species were added to the opposite sides of the membrane.

### Example 3

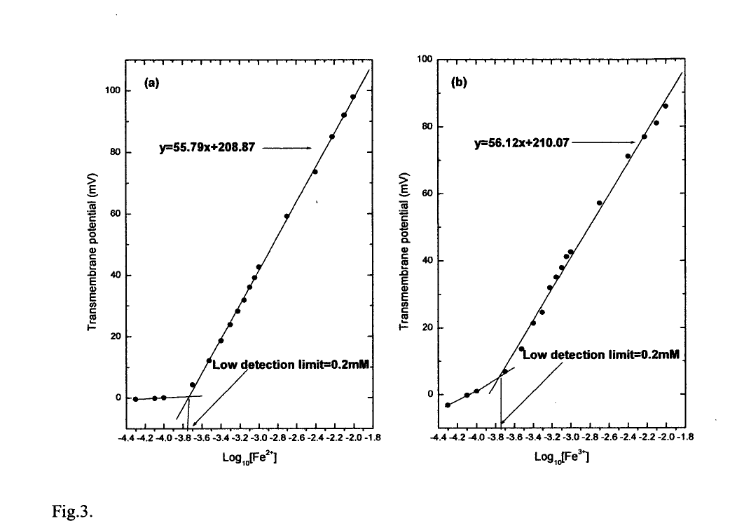

FIG. 3(a, b) demonstrates similar changes for Fe²⁺ and Fe³⁺, respectively. In all cases the initial potential was approximately zero, but it changed after addition of redox active components. The sign of potential in all cases corresponds to electron transport trough the membrane from the reducing to the oxidizing agent.

The slopes of calibration curves in all four cases were close to the ideal Nemstian slope of 59 mV per decade but decreased at low concentrations of the species. The lower detection limits estimated from the interception of the linear regressions for higher and lower concentration ranges for Fe(CN)₆⁴⁻/Fe(CN)₆³⁻ and Fe²⁺/Fe³⁺ were 0.1 mM and 0.2 mM, respectively.

### Example 4

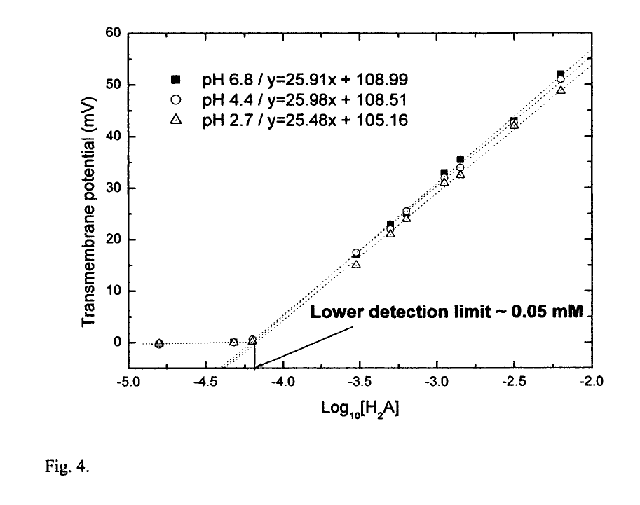

This example presents the calibrations for ascorbic acid based on the maximum potential after each addition. Small amount of EDTA was initially added into the ascorbic acid solution in order to inhibit effects of trace metals as possible catalysts of oxidation. Opposite side of the membrane had 0.01M K₃Fe(CN)₆. Because pKa of ascorbic acid in water is ˜4.3, the calibrations were conducted at pH 2.7, 4.4, and 6.8 respectively, adjusted with buffer solutions. FIG. 4 demonstrates good linear response of transmembrane potential vs. the logarithm of ascorbic acid concentration in all three cases. The slopes at different pH were close to each other, and were approximately 59/2 mV, corresponding to the two-electron oxidation of ascorbic acid by PANI membrane.

The lower detection limit was as low as 0.05 mM in all three cases. Sensitivity of the method at pH near neutral makes it attractive for investigations of physiological liquids.

### Example 5

Calibrations with organic redox dyes such as Neutral Red and Nile Blue were performed in the concentration range from 0.03 mM to 100 mM. The dyes were dissolved in 0.01M phosphate buffer solution (pH˜6.4). The solution in the opposite (reference) side in both cases was 0.01M K₃Fe(CN)₆, pH 6.4. Table 1 shows that the linear slopes in calibrations of these two species were both close to the ideal Nerstian slope for one-electron transfer. The correlation coefficients for the linear functions were 0.98 and 0.97 for Neutral Red and Nile Blue, respectively. The lower detection limits for these two species were approximately 0.1 mM.

During calibration of the third dye, N-phenylanthranilic acid, which is a strong oxidant, (standard redox potential 0.89V vs. NHE), the solution in the opposite side of the membrane was ferrocyanide instead of ferricyanide (Table 1). The slope was again close to the ideal Nemstian slope, and the lower detection limit was 0.30 mM. In this case, the experiments were conducted in the relatively low concentration range of N-phenylanthranilic acid from 0.03 mM to 1 mM because of its poor solubility in water.

TABLE 1
Calibration results for the redox active dyes Neutral Red, Nile Blue
and N-phenylanthranilic acid. Solutions separated by the membrane
were in 0.01M phosphate buffer, pH 6.4.

| | Solution in the | | Lower detection |
|---|---|---|---|
| Redox dyes | opposite side | Slope, mV | limit, mM |
| Neutral Red | 0.01M K₃Fe(CN)₆ | 55.23 | 0.13 |
| Nile Blue | 0.01M K₃Fe(CN)₆ | 55.87 | 0.09 |
| N-phenylanthranilic | 0.01M K₄Fe(CN)₆ | 55.92 | 0.30 |
| acid | | | |

Redox Reaction Through PANI-CSA Membrane

### Example 6

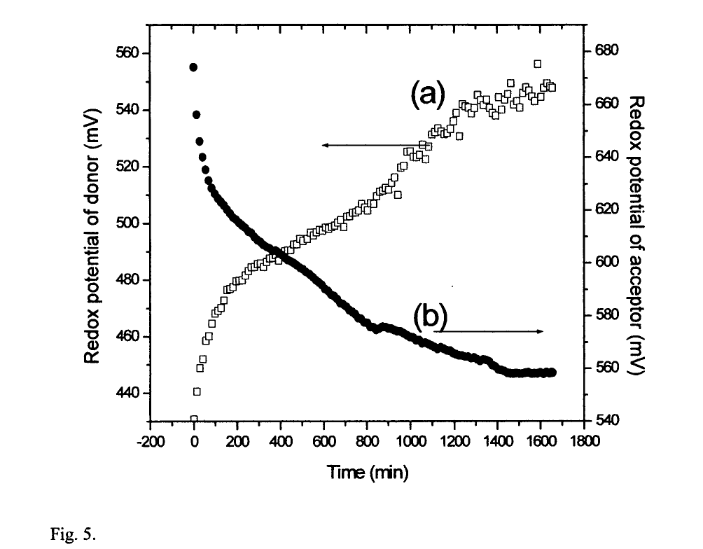

FIG. 5 shows typical kinetics of redox potentials changes in both solutions due to the transmembrane redox reaction across the PANI-CSA membrane. In this case FeCl₃ solution was used as the oxidizing agent, and FeCl₂ solution as the reducing agent. Redox potentials in this case were measured with Pt electrodes versus Ag/AgCl reference electrodes. The addition of the redox substances without notable time lag results in the rise of redox potential in the oxidizing solution and the decrease of the redox potential in the reducing solution. Finally both solutions have the redox potential close to 560 mV. This example demonstrates the transfer of electrons (redox equivalents) from the electron donor phase to the acceptor phase through the PANI-CSA membrane.

Transmembrane Potential and Difference of Redox Potentials in Two Solutions

During the transmembrane redox reaction the magnitude of the transmembrane potential was measured as the difference of potentials between a pair of Ag/AgCl electrodes separated by the membrane.

### Example 7

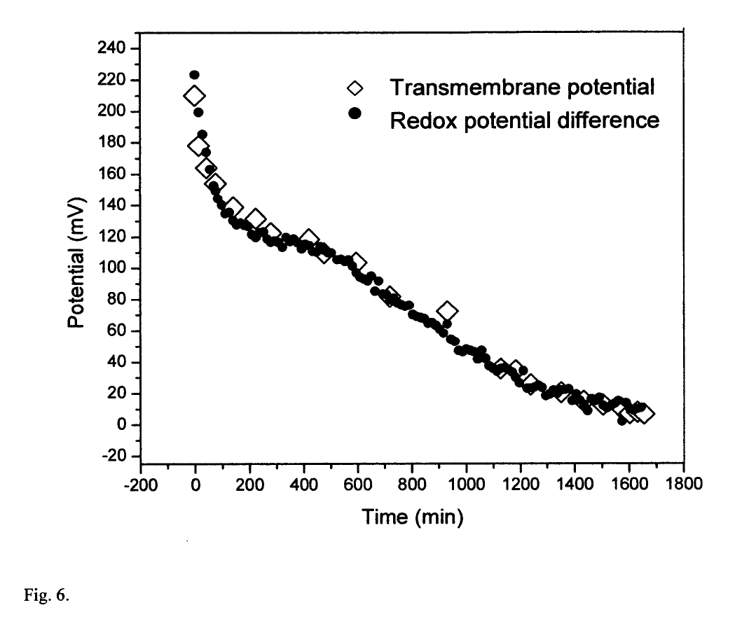

For the transmembrane redox reaction of Fe³⁺ and Fe²⁺ at acidic pH the transmembrane potential was exactly equal to the difference of the two redox potentials in aqueous solutions separated by the membrane and finally decreased to a small (˜4 mV) positive value (FIG. 6).

### Example 8

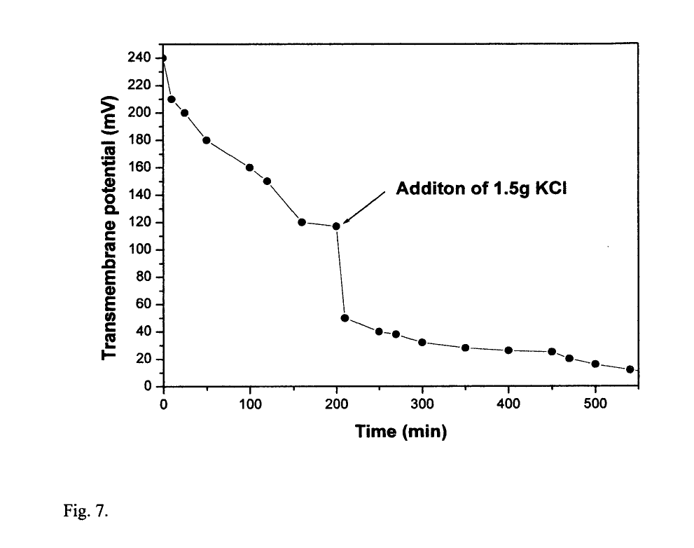

It is possible to conduct transmembrane reaction even at pH˜6, what is demonstrated for redox reaction between K₃Fe(CN)₆ and K₄Fe(CN)₆ (FIG. 7). The membrane was redox conductive, and addition of KCl into the oxidant resulted in an immediate decrease of the transmembrane electrical potential, corresponding to the coupled counter transport of Cl⁻ and electrons through the membrane. This example demonstrates that the transmembrane potential is sensitive to the redox processes in aqueous solutions and can be used for monitoring of these processes.

### Example 9

This example describes theoretical dependence of transmembrane electrical potential on redox potentials in aqueous solutions. Transmembrane potential is a mixed potential, determined by exchange currents due to parallel processes of redox reactions and anion transport. The results of redox calibrations (FIG. 2-FIG. 4) can be well explained with the equation 1:

$$Δ Φ = \frac{2.3 RT}{F} log \{ \frac{{[ Red ]}_{1}}{{[ Ox ]}_{1}} + {{α}_{1} [ {Cl}^{-} ]}_{1} \} - \frac{2.3 RT}{F} log \{ \frac{{[ Red ]}_{2}}{{[ Ox ]}_{2}} + {{α}_{2} [ {Cl}^{-} ]}_{2} \} \qquad ( 1 )$$

where ΔΦ is the transmembrane electrical potential difference, mV; 1 and 2 correspond to the reducing and oxidizing solutions, respectively; the coefficient α can be slightly different for two different sides of the membrane in contact with the first and second solutions, respectively.

The permeability of Cl⁻ anions through PANI films is much higher than that of ferricyanide and ferrocyanide ions, so it is reasonable to include only an anion Cl⁻ as a potential forming permeable anion. As long as Cl⁻ concentration is the same in both sides, the value of potential at low concentrations of redox components is near zero, which corresponds to the experimental results. When Cl⁻ was added into the oxidant solution, transmembrane potential decreased (FIG. 7), which also can be explained by the equation 1.

The permeability of Cl⁻ anions is much lower than the corresponding value for electron exchange, i.e. α<<1. In this case at low Cl⁻ concentration we have

$$Δ Φ = \frac{2.3 RT}{F} log \frac{ {{[ Red ]}_{1} [ Ox ]}_{2} }{{{[ Ox ]}_{1} [ Red ]}_{1}} \qquad ( 2 )$$

This equation explains the experimental fact that the transmembrane potential is equal to the difference of redox potentials in aqueous solutions (FIG. 6).

### Example 10

This example illustrates how concentration of one redox active substance can be measured and demonstrates the relationship of the low limit of sensitivity to chloride concentration. If the concentration of only component [Red]₁ is altered, the equation 1 can be simplified to the well known form;

$$Δ Φ = {const}_{1} + \frac{2.3 RT}{F} log \{ {[ Red ]}_{1} + {{k}_{1} [ {Cl}^{-} ]}_{1} \} \qquad ( 3 )$$

where coefficient k₁ is proportional to the oxidant concentration. When the Red concentration is low, the slope decreases from the ideal one, which determines the low limit of sensitivity.

If only the oxidant concentration changes in the second solution, the corresponding equation is

$$Δ Φ = {const}_{2} - \frac{2.3 RT}{F} log \{ \frac{{k}_{2}}{{{[ {Cl}^{-} ]}_{2} [ Ox ]}_{2}} + 1 \} \qquad ( 4 )$$

In this case the coefficient k₂ is proportional to the reducing agent concentration. Evidently at high Cl⁻ concentration the membrane looses its sensitivity to the low oxidant concentrations.

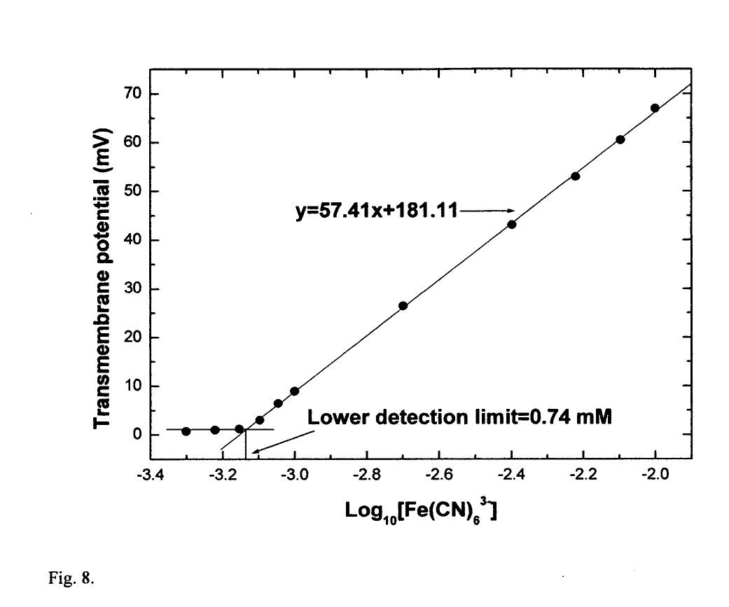

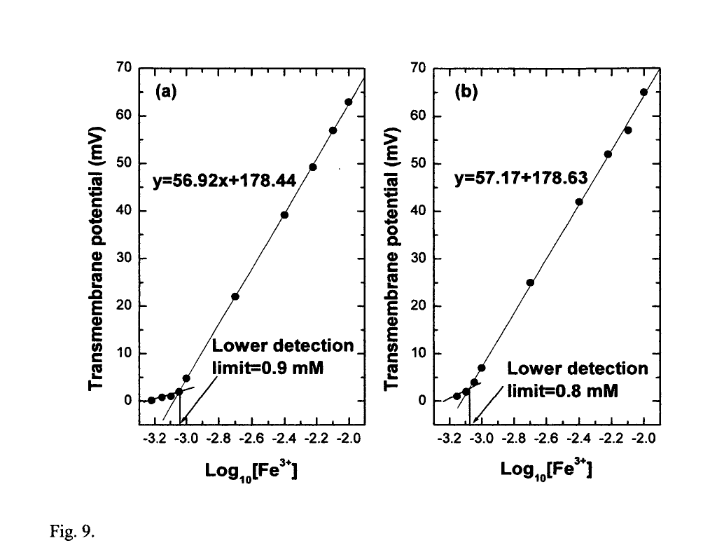

The influence of Cl⁻ concentration on the lower detection limit for an oxidant at neutral pH was confirmed by the results shown in FIGS. 8 and 9. In the presence of 1M KCl in both solutions the lower detection limit for K₃Fe(CN)₆ increased from 0.1 mM observed in the absence of KCl (FIG. 2) to 0.74 mM. The calibration results for FeCl₃ (FIG. 9) also demonstrate that the lower detection limit for Fe³⁺ was increased from 0.2 mM at low Cl⁻ concentration (FIG. 3) to 0.8 mM in the presence of 1M HCl and around 0.9 mM in the presence of 0.1M HCl+1M KCl.

### Example 11

Without redox components the transmembrane potential is formed only by ion transport and not due to the redox processes. Equation 1 in this case is reduced to Nernst equation describing transmembrane potential formed due to Cl⁻:

$$Δ Φ = \frac{2.3 RT}{F} log \frac{{[ {Cl}^{-} ]}_{1}}{{[ {Cl}^{-} ]}_{2}} \qquad ( 5 )$$

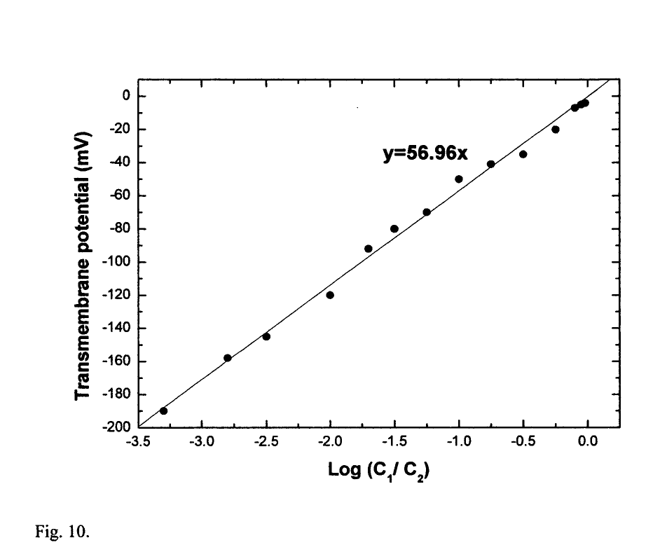

FIG. 10 presents experimental results with CSA doped PANI membrane. Evidently in the absence of redox active species it is possible to measure Cl⁻ concentration at least from 0.05 mM to 100 mM at pH˜6.

CSA doped PANI membranes are redox active both at acidic and neutral pH. This is an essential advantage in comparison to the HCl doped PANI membrane, where at least one of the solutions must be acidic for the membrane to be electroactive.

We claim:

1. A method for determining a redox potential of an unknown aqueous solution, comprising the steps of:
i. contacting a membrane with an unknown aqueous solution and a known aqueous solution or an electrode, separated by this membrane and comprised of polymers from a class of synthetic metals;
ii. measuring a difference in electric potential between a first electrode in the unknown solution and a second electrode in the known solution or in direct contact with the membrane; and
iii. calculating a redox potential of the unknown aqueous solution based on a redox potential of the known aqueous solution and the measured difference in electric potential.

2. A method for determining a concentration of a redox active substance in an unknown aqueous solution, comprising the steps of:
i. contacting a membrane with an unknown aqueous solution and a known aqueous solution, separated by the membrane comprised of doped polyaniline;
ii. measuring a difference in electric potential between a first electrode in the unknown solution and a second electrode separated by a membrane; and
iii. calculating a concentration of a redox active substance in the unknown aqueous solution based on a concentration of a redox active substance in the known aqueous solution and the measured difference in electric potential.

3. The method of claim 2, in which the electrodes are made from silver and silver chloride.

4. The method of claim 2, in which the membrane is doped with a dopant d,l-camphor sulfonic acid (CSA) in a ratio of CSA to polyaniline between 0.01 g/g and 1 g/g.

5. The method of claim 2, in which the membrane is doped with a dopant selected from aromatic and long chain aliphatic sulfonic acids, including alkylbenzene sulfonic acids, nitrobenzene sulfonic acids, toluene sulfonic acids, anthraquinone sulfonic acids, octane sulfonic acid.

6. The method of claim 2, in which the membrane comprises a mixture of polyaniline or sulfonated polyaniline and polymers including Nafion, polyvinyl sulfonic acids, polystyrene sulfonic acids, sulfonated cyclodextrin salts, and composites with sulfonated polyether.
